(19) United States
(12) Patent Application Publication
(10) Pub. No.: US 2005/0077970 A1
(43) Pub. Date: Apr. 14, 2005

(54) Method and device for controlling an oscillator

(75) Inventors: Nicola Da Dalt, Villach (AT); Sven Derksen, Villach (AT)

Correspondence Address: Maginot, Moore & Beck;Bank One Tower, Suite 3000, 111 Monument Circle, Indianapolis, IN, 46204, US

(73) Assignee: Infineon Technologies AG, Munchen (DE)

(21) Appl. No.: 10/920,707

(22) Filed: Aug. 18, 2004

(30) Foreign Application Priority Data
Aug. 19, 2003 (DE) 103 38 092.2

(51) Int. Cl. H03L 7/00

(52) U.S. Cl. 331/16

(57) ABSTRACT

A method and a device for controlling an oscillator (1) are proposed, wherein a first control signal (b) is generated depending on an output signal (e) of the oscillator (1) and on a first reference signal (a), and a second control signal (d) is generated depending on the first control signal (b) and on a second reference signal (c), and wherein the oscillator (1) is subjected to the first control signal (b) and to the second control signal (d) and generates the output signal (e) with a frequency dependent on the first control signal (b) and on the second control signal (d). A low-noise phase locked loop with a large possible frequency range can be realised by such a method and such a device.

The present invention relates to a method and a device for controlling an oscillator. In particular the invention relates to a method and a device for controlling an oscillator of a phase locked loop for generating a timing (clock) signal for an electronic circuit.

A high-quality clock signal source is often a basic prerequisite in present day chip architectures. A clock signal with very low phase noise and thus low jitter is a prerequisite for high-speed transceiver circuits or sampling applications that utilise high-performance analog/digital or digital/analog converters. The most stringent requirements on phase noise are found in the case of wireless receiver applications, in which normally a frequency generator is used as local oscillator for converting the frequency of the received RF (Radio Frequency) signal to a lower frequency.

The frequencies employed in these applications are normally rather high and lie in the range from a few hundred MHz up to the GHz range. Such frequencies cannot be generated with a quartz oscillator, and other low-noise oscillators, such as for example SAW (Surface Acoustic Wave) resonators, are generally expensive, consume a relatively large amount of power and cannot be integrated. Accordingly an oscillator in a phase locked loop (PLL), is generally used, with which a clock signal can be generated having a frequency that is a multiple of a reference frequency. This reference frequency is in turn typically generated by a quartz oscillator.

A typical such phase locked loop is illustrated in FIG. 6. In this, a phase detector 4, for example a phase frequency detector, compares the phases of a reference signal a and a clock signal f. This clock signal f is generated by means of a frequency divider 14 from an output signal e of a controllable oscillator 1. The controllable oscillator 1 may for example be a voltage controlled oscillator (VCO).

The phase detector 4 generates a signal with which a charge pump 5 is controlled. The charge pump 5 may in this connection contain for example controllable or switchable current sources. In this way a loop filter 2 is subjected to a signal g generated by the charge pump 5, the charge being proportional to the phase difference between the reference signal a and the clock signal f. The loop filter 2 normally has a PI transmission function, i.e. a transmission function with a proportional component and an integral component and is designed in the form of a low-pass filter. The output signal of the loop filter 2 controls the oscillator 1; the output signal may in this connection be a current signal or a voltage signal.

By means of this circuit the oscillator 1 is controlled overall so that the reference signal a and the clock signal f always have the same phase and thus also the same frequency. The output signal e then has a frequency that is larger, by a multiple dependent on the frequency divider 14, than the frequency of the clock signal f. In this state the phase locked loop is described as “locked-in” or “adjusted”.

The main sources of noise in such a phase locked loop are typically the oscillator 1, the loop filter 2 and the charge pump 5. If the reference signal a is generated by a quartz oscillator, the contribution of the reference noise to the noise of the output signal e is generally negligible.

In order to reduce the noise caused by the oscillator 1, normally LC voltage-controlled oscillators (LC-VCO) with a high Q factor are used.

The only possible way of reducing the intrinsic noise of the loop filter 2 is to implement it with very large capacity capacitors. With an on-chip implementation this means that large regions are necessary on the chip just for the implementation of the capacitors.

In order to reduce noise caused by the charge pump, it is usual to use high currents (of the order of magnitude of several mA) to operate the charge pump. Since the MOS (Metal Oxide Semiconductor) transistors normally used as current sources in such a charge pump have to be kept in a state of saturation despite the high currents, the charge pump is supplied with a voltage that is larger than the supply voltage of the remaining phase locked loop. Occasionally even special high-voltage transistors are used for the implementation of the current sources in the charge pump.

Although in general fully integrated solutions are preferred, on account of the problems outlined above with phase locked loops with very low phase noise some of the components of the PLL have been implemented externally, for example the oscillator and part of the loop filter, for example the aforementioned large capacity capacitors. For reasons of cost it is however desirable to avoid as far as possible the use of such external components or the use of special masks for the implementation of special components on the chip.

The possible solutions outlined above aim to reduce the intrinsic noise generated by the various components of the PLL. A second possibility is to minimise the transmission function from the point at which the noise is generated to the output of the PLL. One possibility in this connection is to optimise the bandwidth of the PLL. In applications in which the reference signal is predetermined by a very low-noise source such as a quartz oscillator, the bandwidth of the PLL must be chosen as high as possible in order to reduce the noise component of the oscillator. For reasons of stability the PLL bandwidth must however be somewhat lower than the reference frequency of the reference signal. Normally an upper limit for the bandwidth lies at about 1/10 of this reference frequency. Furthermore, in various applications the bandwidth of the PLL is determined by a specification required by the application and cannot be altered in order to reduce the noise.

Another possibility is to reduce an amplification Kco of the oscillator. In fact, it can be shown that for a given bandwidth of the PLL the noise transmission functions from the charge pump and from the loop filter to the output of the phase locked loop are proportional to the amplification Kco of the oscillator. The power spectral density of the noise generated by a balanced charge pump is proportional to the charge pump current, while the power spectral density of the noise generated by the loop filter is independent of the charge pump current and depends only on the resistors and capacitors used in the loop filter.

If the amplification Kco is reduced by a factor M and the charge pump current is increased by the same factor, then the bandwidth of the PLL is not altered. The power spectral density of the charge pump noise at the output of the phase locked loop is however reduced by the same factor M, whereas the power spectral density of the noise generated by the loop filter is reduced by a factor M², at the output of the phase locked loop.

The problem associated with this procedure is that, due to the reduction of the amplification Kco, the range in which the frequency of the oscillator can be adjusted is at the same time reduced. In addition a central frequency of each oscillator may vary to a certain extent on account of variations in the supply voltage, temperature or also on account of process variations. These variations are also termed PVT (Process Voltage Temperature) variations. If the adjustment range becomes too small and a drift of the central frequency on account of PVT variations is larger than the adjustment range itself, it may happen that the phase locked loop cannot lock in.

In order to solve this problem it is known to use oscillators with an analog control input and a digital control input. The analog control input corresponds to the conventional control input of an oscillator. When controlling the oscillator via this input the oscillator behaves like a conventional oscillator with low amplification Kco, i.e. it exhibits a “flat” frequency behaviour dependent on the analog input signal. Through the digital input the oscillator can be switched in discrete steps between various frequency ranges by for example activating various inductances. This method enables a PLL with a low amplification to be realised, which nevertheless can cover a large specified frequency range.

The disadvantage of this method is that the adjustment range is altered in discrete steps over the digital control input. If for example the corresponding digital control signal is chosen so that, during start-up, the PLL can lock in and then variations, for example in the temperature or in the supply voltage, occur during operation of the PLL, the chosen adjustment range could change in such a way that the desired output frequency of the PLL is no longer covered. In this case the PLL is either no longer locked-in, or the digital control signal is changed on account of an automatic or semi-automatic frequency check, which generates an undesired phase transient and frequency transient at the output of the PLL.

An object of the present invention is accordingly to provide a method and a device for controlling an oscillator, in which an output frequency of the oscillator can vary over a wide range and in addition an output signal of the oscillator exhibits a low noise.

This object is achieved according to the invention by a method according to claim 1 and by an apparatus according to claim 16. The subclaims define preferred or advantageous examples of implementation of the method and of the apparatus.

According to the invention it is proposed, in order to control an oscillator, to generate a first control signal depending on an output signal of the oscillator and on a first reference signal, to generate a second control signal depending on the first control signal and on a second reference signal, and to control the oscillator with the first control signal and with the second control signal so that the oscillator generates the output signal at a frequency dependent on the first control signal and on the second control signal.

The first control signal and the second control signal may in particular be analog signals. Due to the use of two control signals and two reference signals, the oscillator can be controlled by the first control signal so that it generates a desired frequency depending on a frequency of the first reference signal, wherein in addition the first control signal lies close to a desired value that is predetermined by the second reference signal. This desired value may lie in particular in the middle of a value range of the first control signal.

Advantageously the output frequency of the oscillator can be controlled by the first control signal over a smaller range than with the second control signal, with the result that the first control signal corresponds to a fine regulation and the second control signal corresponds to a coarse regulation. In this case there is preferably a “flatter” dependence of the frequency of the output signal on the first control signal than on the second control signal, and a time constant that characterises a change of the frequency by the first control signal is preferably significantly smaller than a time constant that characterises the regulation of the frequency by the second control signal if the output signal of the oscillator changes. In this way a frequency regulation takes place substantially through the first control signal, and can be executed in a low-noise manner. Only if the frequency of the output signal is to be changed by a larger amount does the second control signal dominate.

The frequency regulation by the first control signal and by the second control signal is in this connection preferably continuous or stepless.

In a preferred use the first control signal is generated in a phase locked loop depending on a phase difference between a signal dependent on the output signal, in particular a frequency-divided output signal, and the first reference signal. The second reference signal may be generated depending on a difference between the first control signal and the second reference signal. The first control signal and the second control signal may be current signals or also voltage signals. The two control signals may also be differential signals, i.e. signals that are transmitted via two lines, in which the size of the signal is determined by the difference between the sizes of the signals in the two lines.

As oscillator there may in particular be used a voltage-controlled oscillator whose frequency depends on an LC element. The capacity of the LC element is in this connection preferably formed by at least two separately controllable capacitors, wherein one of the two capacitors is controlled by the first control signal and the other of the two capacitors is controlled by the second control signal.

The second control signal can be generated by an amplifier, in particular a transconductance amplifier, which amplifies in particular a difference between the first control signal and the second reference signal in order to generate the second control signal. In order to reduce a time constant of the second control signal, circuit means may be provided that are closed in a certain timing ratio, wherein the second control signal can be changed only when the circuit means are closed.

The present invention is particularly suitable for use in PLL-based frequency synthesiser circuits of chip architectures, e.g. in low-noise communication devices such as for example wireless receivers, though the invention is not restricted to the latter but can in principle be used in all cases where it is desired to generate a low-noise output signal variable over a wide frequency range by means of a controllable oscillator.

The invention is described in more detail hereinafter with the aid of preferred examples of implementation and with reference to the accompanying drawings, in which:

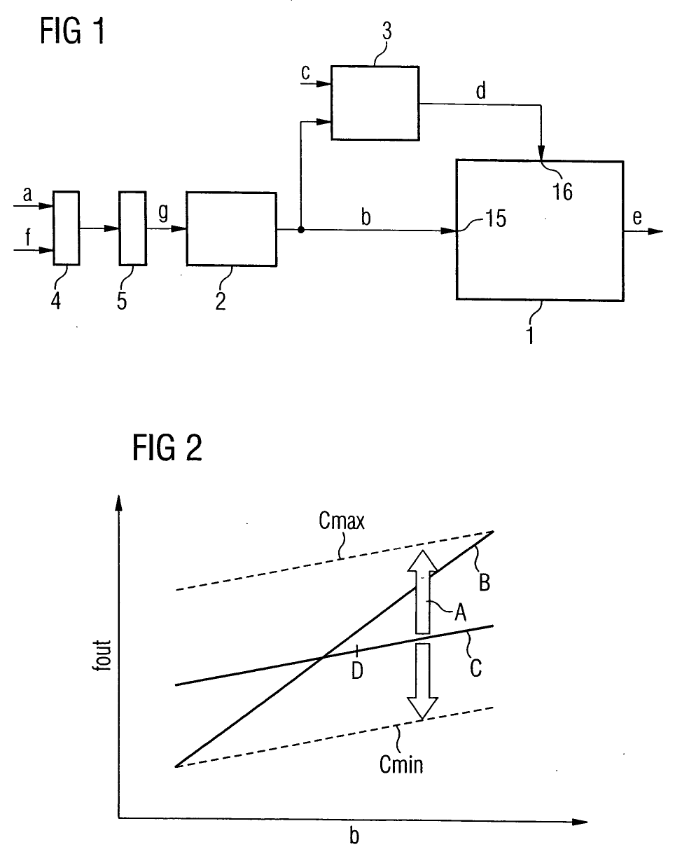

FIG. 1 is a block diagram of an example of implementation according to the invention of a device for controlling an oscillator,

FIG. 2 is a diagram that shows diagrammatically the dependence of a frequency of an output signal of the oscillator on control signals,

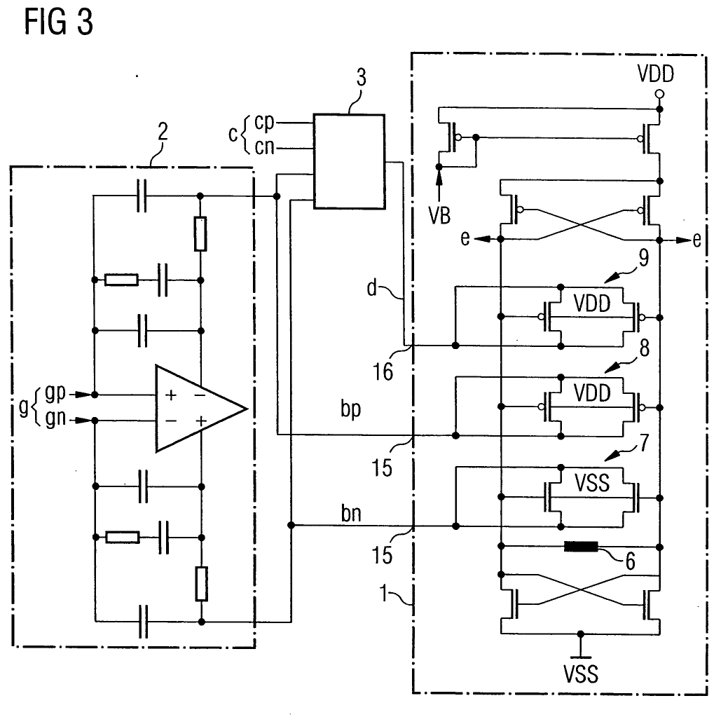

FIG. 3 shows a possible realisation in terms of circuitry of an example of implementation of FIG. 1,

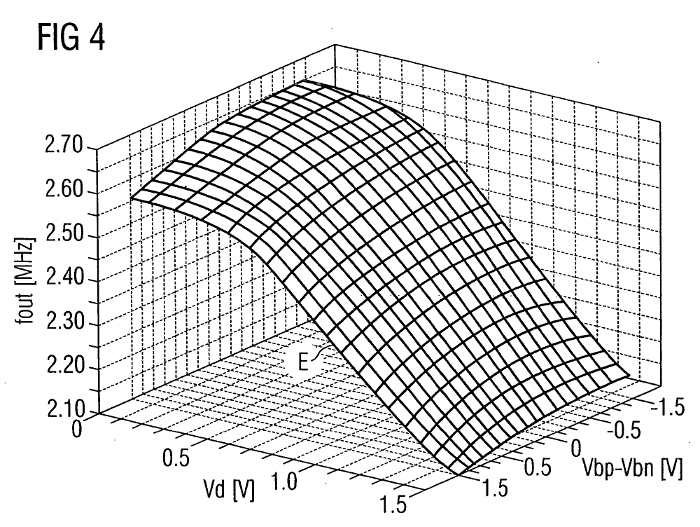

FIG. 4 is a simulation of a frequency dependence of the output signal of the oscillator illustrated in FIG. 3,

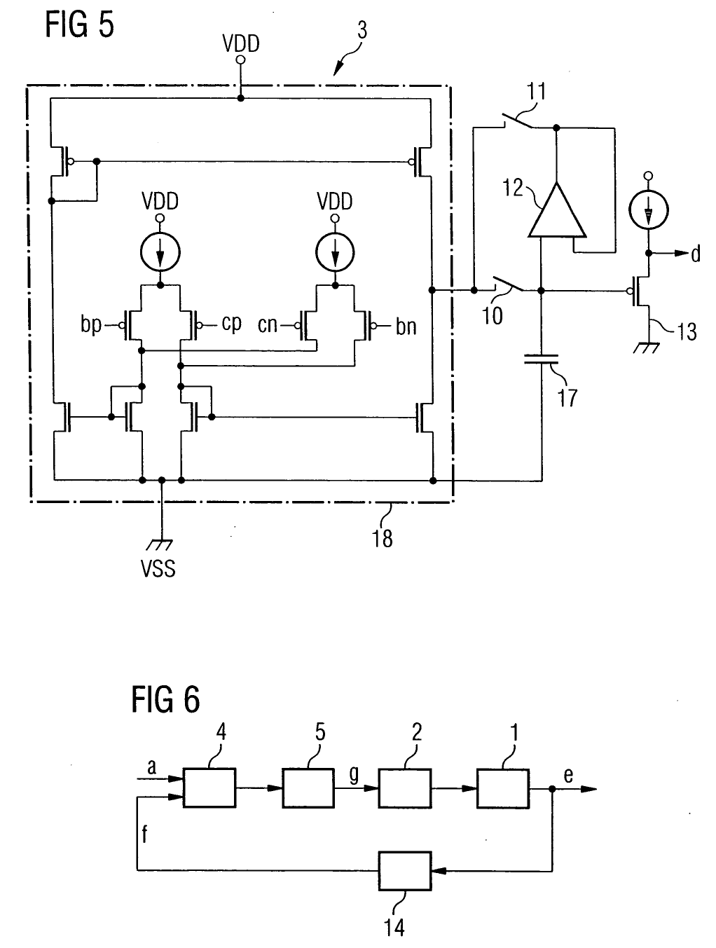

FIG. 5 shows a possible realisation in terms of circuitry of coarse control devices illustrated in FIGS. 1 and 3, and

FIG. 6 is a block diagram of a phase locked loop according to the prior art.

FIG. 1 shows a block diagram of a device according to the invention for controlling an oscillator 1. Components that perform the same function as components of the phase locked loop explained in the introduction to the description with reference to FIG. 6 are identified by the same reference numerals. As regards the mode of operation of the components, further details are given in the description to FIG. 6.

In the illustrated device a first reference signal a and a clock signal f are fed to a phase detector 4, whereby the signal f can be generated for example by means of a timing divider from an output signal e of the oscillator 1, as illustrated in the already described FIG. 6. The first reference signal a defines the desired frequency for the output signal e of the oscillator 1. Depending on the determined phase difference between the first reference signal a and the clock signal f, the phase detector 4 controls a charge pump 5. This may for example contain switchable current sources and generates a current signal g that is proportional to the determined phase difference. The current signal g is fed to a loop filter 2 that may be realised as in the conventional phase locked loop of FIG. 6, and generates a low-pass-filtered first control signal b.

The first control signal b is fed to the oscillator 1 at a first control input 15. Furthermore the first control signal b is fed to a coarse control device 3. In addition a second reference signal c is fed to the coarse control device 3, whereby the said coarse control device 3 generates, depending on the first control signal b and on the second reference signal c, a second control signal d that is fed to the oscillator at a second control input 16.

The oscillator generates the output signal e, wherein the frequency of the output signal e depends on the first control signal b and on the second control signal d.

The various occurring signals a-f may in this connection in each case be voltage or current signals and may exist independently of one another as differential signals or as signals transmitted simply via a line. In the present example of implementation the circuit is designed so that the signals are analog signals. In principle however it is also conceivable for some or all of the signals to be digital signals.

FIG. 2 shows diagrammatically a possible dependence of the output frequency fout of the output signal e on the first control signal b and on the second control signal d. The first control signal b (for example a voltage of the first control signal b) is plotted in arbitrary units on the x-axis, while the frequency fout is plotted, likewise in arbitrary units, on the y-axis. For a fixed value of the second control signal d the frequency fout varies depending on the first control signal b, as illustrated by the curve C. The gradient of the curve C is in this connection relatively small, which corresponds to a low amplification Kco of the oscillator 1 whereby, as described in more detail in the introduction, a low-noise output signal can be achieved. By means of the second control signal d the curve C can be displaced in the vertical direction continuously between a minimum curve Cmin and a maximum curve Cmax, as illustrated by arrows A. The frequency range illustrated by the curve B thus represents the overall adjustment range of the frequency fout. Due to the fact that the curve C is displaced continuously and not in discrete steps, the transients mentioned in the introduction to the description can be avoided.

Preferably the position of the curve C can be adjusted by the second control signal d so that the first control signal b lies roughly in the middle of the curve C, i.e. roughly at a working point D. This can be achieved if, as second reference signal c, a signal is supplied that corresponds to a first control signal b lying at this working point D. Depending on the specific structure of the various blocks from FIG. 2, another working point D may however also be advantageous and may be adjusted by the second reference signal c.

The function of the coarse adjustment device 3 consists accordingly in comparing a property of the first control signal b (for example a voltage or a current) with the same or another property of the second reference signal c and, if a difference is found, specifying the second control signal d so that this difference is minimised. If for example the first control signal is maintained substantially in the middle of the corresponding adjustment range, as illustrated above, then a phase locked loop comprising the device from FIG. 1 can be prevented from being, due to temperature or voltage fluctuations, in a range in which it can no longer lock in.

In order that the flat curve C can be used effectively to control the noise of the output signal e, the control dynamics of the coarse control device 3 must be slow or very slow with respect to the phase locked loop. In other words, a second time constant associated with the coarse control device or with a change of the second control signal d must be substantially larger than a first time constant associated with a change of the first control signal, which corresponds to the inverse of the bandwidth of the phase locked loop. Typically the second time constant is for example about 1 msec, whereas the first time constant is about 1 μsec, i.e. the time constants differ by a factor of 1000. However, depending on the specific application a smaller difference, for example a factor of 100, may be sufficient.

The fact that a working point of the first control signal can be specified by means of the second reference signal c also enables other circuit blocks, such as for example the charge pump 5, to be optimised.

FIG. 3 shows possible realisations in terms of circuitry of the oscillator 1 and of the loop filter 2 from FIG. 1.

The loop filter 2 is in this connection conventionally constructed as a low-pass filter with an operational amplifier, capacitors and resistors, these components being connected up as shown in FIG. 3. The loop filter 2 is designed as a differential filter, i.e. the input signal g and the first control signal b are differential signals. The input signal g is transmitted as two components gp and gn on two lines, and the magnitude of the signal g is manifested as the difference between the magnitude of the partial signal gp and the magnitude of the partial signal gn. The magnitude is understood in this context to mean the amplitude of the voltage in the case of a voltage signal, and the current intensity in the case of a current signal. In the same way the first control signal b consists of components bp and bn.

In FIG. 3 the reference signal c is also formed as a differential signal, i.e. its components cp and cn are fed together with the components bp and bn to the coarse control device 3, which will be described in more detail hereinafter.

The oscillator 1 is supplied with a negative supply voltage VSS, a positive supply voltage VDD and an additional bias voltage VB. The positive supply voltage VDD and the bias voltage VB are in each case applied via PMOS transistors, as illustrated in FIG. 3. Its core component is an LC oscillating circuit, comprising an inductance 6 and varactors 7, 8, 9. The varactor 7 is a small NMOS varactors, i.e. it has a relatively small capacity and/or can be regulated over a relatively small capacity range. Correspondingly, the varactor 8 is a small PMOS varactor. The varactor 9 is a large PMOS varactor with a correspondingly larger capacity and a larger adjustment range.

The varactors 7 and 8 are controlled by the first control signal b, which is fed via the first control input 15. In this connection the component bn of the first control signal b controls the NMOS varactor 7 and the component bp of the first control signal b controls the PMOS varactor 8. The PMOS varactor 9 is controlled by the second control signal d, which is fed via the second control input 16 and, in contrast to the first control signal b, is transmitted via an individual line. The output signal e is decoupled by means of cross-coupled PMOS and NMOS transistors. The voltage supply serves in this connection to compensate losses of the oscillating circuit.

In this example of implementation the first control signal b and the second control signal d are voltage signals. Furthermore, according to this example of implementation the individual components of the oscillator 1 are connected to one another as shown in FIG. 3, though modifications in terms of circuitry may be implemented without altering the mode of operation of the oscillator 1.

FIG. 4 shows the output frequency fout in MHz of the thereby generated output signal e depending on the voltage Vd of the second control signal d and on the difference voltage (Vbp−Vbn) of the second control signal. The three-dimensional curve E thereby represents the output frequency fout. As can be seen in the example, the output frequency fout alters over the whole regulating range of the first control signal by about 0.1 MHz, whereas a regulation of about 0.5 MHz is possible by means of the second control signal. For a fixed Vd the curve E has a relatively small gradient, whereas with a fixed (Vbp−Vbn) it has a larger gradient. In other words, the (partial) derivative of the frequency fout after the first control signal b is less than the (partial) derivative of the frequency fout after the second control signal d.

As can be seen, the behaviour in the case of a fixed voltage Vd need not be the same for all voltages Vd, but may vary somewhat over the adjustment range. The same is also true for a fixed voltage (Vbp−Vbn).

FIG. 5 shows a possible realisation in terms of circuitry of the coarse control device 3 from FIG. 3. The coarse control device 3 comprises in this connection a conventional transconductance amplifier 18, in which the signals bp and cp and cn and bn, which have already been discussed on the basis of FIG. 3, are in each case fed to an input difference pair of PMOS transistors. The transconductance amplifier 18 generates at its output a current that is proportional to the voltage difference (Vcp−Vcn)−(Vbp−Vbn), in which Vxx denotes the voltage of the signal xx. The output current that is thereby generated loads a capacitor 17, at which the second control signal d can be tapped via a buffer. In the present example of implementation the buffer is formed by a PMOS transistor 13 connected as source follower. Such a circuit construction is also termed a gm-C integrator.

In addition a switch 10 is provided, via which the capacitor 17 can be separated from an output of the transconductance amplifier 18. When the switch 10 is open no charge can therefore be transferred to the capacitor 17, and the second control signal d remains unchanged, whereas when the switch 10 is closed the second control signal d can be altered so that switching between two different operating modes of the coarse control device 3 can be effected with the aid of the switch 10.

In order to prevent a saturation of the output of the transconductance amplifier 18, when the switch 10 is open, a dummy circuit leg consisting of a buffer 12 and a switch 11 is provided, the switch 11 being operated in a complementary manner to the switch 10. This means that if the switch 10 is open the switch 11 is closed, and vice versa. The purpose of the dummy circuit leg is to keep the potential of the output of the transconductance amplifier 18 at the same potential as a terminal of the capacitor 17 connected to the gate of the PMOS transistor 13 when the switch 10 is open.

As has already been explained, a large time constant is desirable for changes of the second control signal d. For the present example of implementation, this means that a low integration amplification is necessary. This can be achieved in two ways. Firstly, the MOS transistors of the input difference pair to which the signals b and c are applied are operated below their threshold value, which produces a low intrinsic transconductance and thus a low amplification. Furthermore the switch 10 is operated at a timing ratio of about 1:1000, i.e. the switch 10 is closed only in 1 out of 1000 timing cycles. This means that the effective current that charges the capacitor 17 is 1000 times smaller than the output current of the transconductance amplifier 18. With this construction the integration amplification Ki is given by

$$Ki = \frac{gm \cdot α}{C} ,$$

where gm is the transconductance of the MOS difference pair, α is the timing ratio with which the switch is operated, and C is the capacity of the capacitor 17. For example the integration amplification may be chosen to be 1000 rad/sec, whereby the ratio of current levels connected with the input difference pairs according to FIG. 5, which are formed according to FIG. 5 by NMOS transistors, of the transconductance amplifier 18 is 1:1.

Obviously the circuit examples described hereinbefore and illustrated in the figures should be regarded simply by way of example, and other embodiments of the oscillator and of the coarse control device are also possible. For the coarse control device in principle any circuit can be employed that generates a second control signal d dependent on the first control signal b and on the second reference signal, in particular in such a way that a difference of the signals b and c is compensated. In the oscillator 1 varactor diodes are also conceivable instead of the PMOS and NMOS varactors, or the inductance 6 may be altered instead of the capacity.

1-33. (canceled)

34. A method for controlling an oscillator, the method comprising:
generating a first control signal dependent on an output signal of the oscillator and on a first reference signal;
generating a second control signal dependent on the first control signal and on a second reference signal;
subjecting the oscillator to the first control signal and to the second control signal; and
generating the oscillator output signal with a frequency dependent on the first control signal and on the second control signal.

35. The method according to claim 34, wherein the first control signal and the second control signal are analog signals.

36. The method according to claim 34, wherein the first control signal is generated depending on a phase difference between a signal dependent on the output signal and the first reference signal.

37. The method according to claim 36, wherein the signal dependent on the output signal is generated from the output signal by a frequency division.

38. The method according to claim 34, wherein the frequency of the output signal can be varied by means of the first control signal over a first range and by means of the second control signal over a second range, wherein the second range is larger than the first range.

39. The method according to claim 38, wherein the second range is at least five times larger than the first range.

40. The method according to claim 34, wherein the frequency of the output signal of the oscillator is generated, depending on the first control signal and on the second control signal, in such a way that the derivative of the frequency of the output signal according to a signal magnitude of the first control signal is less than the derivative of the frequency of the output signal according to a signal magnitude of the second control signal, wherein the signal magnitude of the first control signal is the same as the signal magnitude of the second control signal.

41. The method according to claim 34, wherein at least one of the first control signal and the second control signal is a current signal.

42. The method according to claim 34, wherein at least one of the first control signal and the second control signal is a voltage signal.

43. The method according to claim 34, wherein at least one of the first control signal and the second control signal is a differential signal.

44. The method according to claim 34, wherein a first time constant that describes a rate of change of the first control signal under a change of the output signal of the oscillator is less than a second time constant that describes a rate of change of the second control signal under a change of the output signal of the oscillator.

45. The method according to claim 44, wherein the first time constant is less than the second time constant by at least a factor of 100.

46. The method according to claim 34, wherein the second reference signal is chosen so that it corresponds to the first control signal substantially in the middle of a signal range associated with the first control signal.

47. The method according to claim 34, wherein the second control signal is generated depending on a difference between the first control signal and the second reference signal.

48. The method according to claim 34, wherein the first reference signal is generated by a quartz oscillator.

49. An apparatus for controlling an oscillator operable to generate an output signal, the apparatus comprising:
means for generating a first control signal at a first control output, the first control signal dependent on the output signal of the oscillator and on a first reference signal;
means for generating a second control signal at a second control output, the second control signal dependent on the first control signal and on a second reference signal;
a first control input to the oscillator, the first control input connected to the first control output; and
a second control input to the oscillator, the second control input connected to the second control output; and
wherein the frequency of the output signal of the oscillator is dependent on the first control signal and on the second control signal.

50. The apparatus of claim 49, wherein the means for generating the first control signal comprise a phase detector including a first input, a second input, and an output, wherein the first input of the phase detector is connected to an output of the oscillator, and wherein the first reference signal is fed to the second input of the phase detector.

51. The apparatus of claim 50, wherein the means for generating the first control signal further comprise a loop filter including an input and an output, wherein the input of the loop filter is connected to the output of the phase detector, and wherein the output of the loop filter is connected to the first control input of the oscillator and to an input of the means for generating the second control signal.

52. The apparatus of claim 49, further comprising a frequency divider including an input and an output, wherein the input of the frequency divider is connected to an output of the oscillator and the output of the frequency divider is connected to an input of the means for generating the first control signal.

53. The apparatus of claim 49, wherein the means for generating the second control signal comprise an amplifier including a first input, a second input and an output, wherein the first input of the amplifier is connected to the first control output, wherein the output of the amplifier is connected to the second control output, wherein the second reference signal is fed to the second input of the amplifier, and wherein the amplifier is designed so that it amplifies a difference between the first control signal and the second reference signal and issues at the output of the amplifier a signal corresponding to the amplified difference.

54. The apparatus of claim 53, wherein the amplifier is a transconductance amplifier.

55. The apparatus according to claim 53, wherein the means for generating the second control signal comprise a capacitance that is designed and is connected to the output of the amplifier in such a way that it integrates the signal present at the output of the amplifier in order to generate the second control signal.

56. The apparatus of claim 49, wherein the means for generating the second control signal comprise switching means that are designed so that the means for generating the second control signal can be switched with the switching means between a first operating mode and a second operating mode, wherein in the first operating mode the second control signal can be changed, and wherein in the second operating mode the second control signal cannot be changed.

57. The apparatus of claim 56, further comprising control means for controlling the switching means, the control means operable to switch the switching means in a specific timing ratio between the first operating mode and the second operating mode.

58. The apparatus of claim 57, wherein the timing ratio between a duration of the first operating mode and a duration of the second operating mode is of the order of magnitude of 1:1000.

59. The apparatus of claim 55, wherein the means for generating the second control signal comprise switching means that are designed so that the means for generating the second control signal can be switched with the switching means between a first operating mode and a second operating mode, wherein in the first operating mode the second control signal can be changed, wherein in the second operating mode the second control signal cannot be changed, and further comprising a dummy circuit connected to the output of the amplifier and to a terminal of the capacitance, wherein the dummy circuit is designed so that the output of the amplifier and the terminal of the capacitance can be maintained at the same potential when the switching means are in the second operating mode.

60. The apparatus of claim 49, wherein the oscillator comprises an LC element for generating the output signal, wherein the LC element comprises a first adjustable capacitance and a second adjustable capacitance, wherein an adjustment input of the first capacitance is connected to the first control input and an adjustment input of the second capacitance is connected to the second control input.

61. The apparatus of claim 60, wherein the second adjustable capacitance has a larger adjustment range than the first adjustable capacitance.

62. The apparatus of claim 60, wherein at least one of the first adjustable capacitance and the second adjustable capacitance comprises a varactor.

63. The apparatus of claim 49, wherein the apparatus is designed such that the frequency of the output signal of the oscillator is generated, depending on the first control signal and on the second control signal, in such a way that the derivative of the frequency of the output signal according to a signal magnitude of the first control signal is less than the derivative of the frequency of the output signal according to a signal magnitude of the second control signal, wherein the signal magnitude of the first control signal is the same as the signal magnitude of the second control signal.

64. The apparatus of claim 49, wherein the apparatus is designed such that a first time constant, which describes a rate of change of the first control signal under a change of the output signal of the oscillator, is less than a second time constant that describes a rate of change of the second control signal under a change of the output signal of the oscillator.

65. The apparatus of claim 64, wherein the first time constant is less than the second time constant by at least a factor of 100.

66. A phase locked loop comprising:
an oscillator comprising a first control input, a second control input, and an output, the oscillator operable to generate an output signal at the oscillator output;
a first control device including a first control output connected to the first control input of the oscillator, the first control device operable to generate a first control signal at the first control output, wherein the first control signal is dependent on the output signal of the oscillator and on a first reference signal; and
a second control device including a second control output connected to the second control input of the oscillator, the second control device also connected to the first control output, the second control device operable to generate a second control signal at the second control output, wherein the second control signal is dependent on the first control signal and on a second reference signal;
wherein the oscillator is designed so that it generates the output signal with a frequency dependent on the first control signal and on the second control signal.
